(19) United States
(12) Patent Application Publication
(10) Pub. No.: US 2009/0091005 A1
(43) Pub. Date: Apr. 9, 2009

(54) Shielding structure for semiconductors and manufacturing method therefor

(76) Inventors: Chung-Er Huang, Xindian (TW); Huang-Chan Chien, Xindian (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/905,999

(22) Filed: Oct. 9, 2007

(51) Int. Cl. H01L 23/552; H01L 21/31

(52) U.S. Cl. 257/659; 438/763; 257/E23.114; 257/E21.24

(57) ABSTRACT

A shielding structure for semiconductor includes a semiconductor substrate, at least one active region defined on the semiconductor substrate, a protecting layer, a shielding layer, and a covering layer. The protecting layer, produced by a semiconductor process, is disposed on the surface of the active region. The shielding layer produced by a semiconductor process is disposed on the surface of the protecting layer. The covering layer covers the shielding layers, and the protecting layer is harder than the covering layer. In the above-mentioned structure, the harder protecting layer is provided to prevent the active regions from heat damage.

### BACKGROUND OF THE INVENTION

1. Field of the Invention

The present invention relates to a radiation shielding structure for semiconductors, and in particular to a radiation shielding structure that protects semiconductors from heat damage.

2. Description of Prior Art

Due to the development of wireless communication technology, the requirements on transmission quality are continuously increasing. For instance, the Federal Communications Commission (FCC) demands that mobile phones and handheld electronic products have to include a GPS function. Moreover, the communication industry faces the challenging task of reducing the size of electronic products and integrating a large variety of functions. While the characteristics of low weight, small size, high quality, low cost and low energy consumption are the main considerations for circuit design and system optimization, radiative shielding of the components also plays an important role with respect to communication quality, because radiation emitted by the components of a wireless communication device may interfere with the wireless device output and because in high radiation environments semiconductor components may suffer damage from environmental radiation. Yet, the currently employed designs for shielding devices are expensive, necessitating a lengthy and labour intensive manufacturing process.

Another important factor is the resistance of device components to stresses imposed by some manufacturing steps. For example, molding resin will soften when the device enters a manufacturing step involving high temperature, and softening of the resin can cause failure of the component.

Therefore, in view of this, the inventor proposes the present invention to overcome the above problems based on his expert experience and deliberate research.

### SUMMARY OF THE INVENTION

The primary object of the present invention is to provide a shielding structure for semiconductors and a manufacturing method therefor comprising a layer that shields radiation emitted by and received by a semiconductor. Furthermore, the process for manufacturing the shielding structure is improved compared to the prior art.

Another object of the present invention is to provide a shielding structure for semiconductors that protects the semiconductor from heat damage by covering it with a harder material.

In order to achieve the above objects, the shielding structure comprises: a semiconductor substrate; at least one active region disposed on one side of the semiconductor substrate; a protecting layer covering the active region; a shielding layer covering the protecting; and a covering layer covering the shielding layer; wherein the protecting layer is harder than the shielding layer.

The present invention also provides a manufacturing method for the shielding structure. The manufacturing method comprises: providing a semiconductor substrate and at least one active region formed thereon; providing a protecting layer disposed on the active region by known semiconductor-manufacturing processes; providing a shielding layer disposed on the protecting layer by known semiconductor-manufacturing processes; and providing a covering layer disposed on the shielding layer.

In order to better understand the characteristics and technical contents of the present invention, a detailed description thereof will be made with reference to the accompanying drawings. However, it should be understood that the drawings and the description are illustrative but not intended to limit the scope of the present invention.

### BRIEF DESCRIPTION OF THE DRAWINGS

FIG. 1 is a schematic view of the first step of manufacturing a shielding structure for semiconductors according to the present invention;

FIG. 2 is a schematic view of the second step of manufacturing a shielding structure for semiconductors according to the present invention;

FIG. 3 is a schematic view of the third step of manufacturing a shielding structure for semiconductors according to the present invention;

FIG. 4 is a schematic view of the preferred embodiment of the insulating layer of the shielding structure for semiconductors according to the present invention; and

FIG. 5 is a flow chart showing the method for manufacturing the shielding structure for semiconductors according to the present invention.

### DETAILED DESCRIPTION OF THE INVENTION

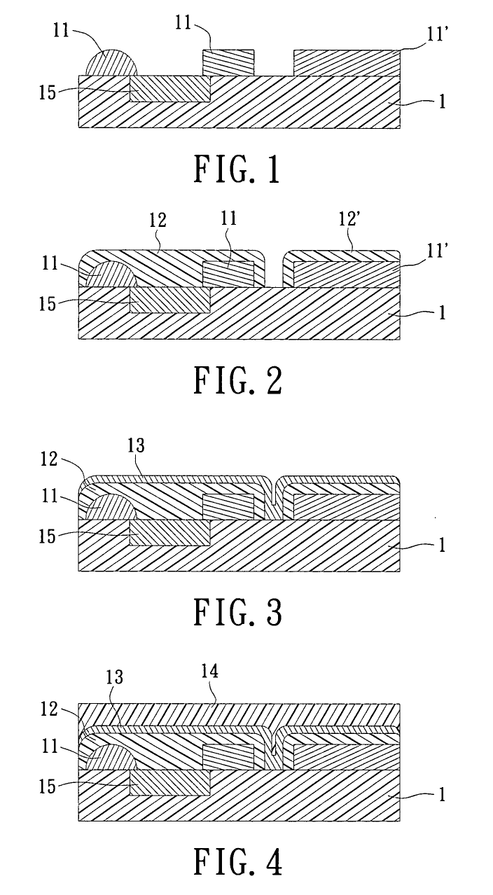

Please refer to FIGS. 1 to 4. The present invention discloses a shielding structure for semiconductors. The shielding structure is provided for shielding high frequency electromagnetic radiation emitted by and falling onto the semiconductor. Moreover, the protecting layer 12 is heat resistant and will maintain the shape of the semiconductor when it is exposed to high temperature.

The shielding structure comprises a semiconductor substrate 1, and in the preferred embodiment the semiconductor substrate 1 is a gallium arsenide (GaAs) substrate. At least one conducting region 15 is formed on one side of the semiconductor substrate 1. The conducting region 15 is applied by semiconductor-manufacturing processes that are familiar to those skilled in the art, such as lithography process or etching process. Note that only one conducting region 15 is shown in the figures for the sake of simplicity.

Furthermore, at least one active region 11 is disposed on the semiconductor substrate 1 electrically connected to the conducting region 15. The conducting region 15 and the active regions 11 are provided to transfer electrical current in the embodiment, three active regions 11 are defined on the semiconductor substrate 1 and each of the active regions 11 has a unique shape, position and connection to the other regions on the semiconductor substrate 1 depending on process parameters and circuit design.

A protecting layer 12 is covering the active regions 11 for protecting said active regions 11. The protecting layer 12 is disposed on active regions 11 by semiconductor-manufacturing processes that are familiar to those skilled in the art. Protecting layer 12 is covering two active regions 11, and protecting layer 12′ is covering active region 11′. The number of active regions 11 covered by a protecting layer 12 is not restricted but can be adjusted according to process parameters and circuit design. The protecting layer 12 is made of tetraethoxysilane (TEOS) or silicon nitride. Tetraethoxysilane (TEOS) or silicon nitride is harder than the semiconductor material and will not be softened by high temperature. Therefore, the active region 11 is protected by the harder protecting layer 12 from deformation under the influence of heat.

A shielding layer 13 is covering the protecting layer 12. The shielding layer 13 is a metal layer applied by a metal sputtering process and has a predetermined thickness so as to shield the signal transmitted from each active region 11. The shielding layer 13 covers both protecting layers 12 and 12′, and the shielding layer 13 is grounded, thus absorbing incoming electromagnetic radiation. In other words, the shielding layer 13 acts as an electrical reference plane so that the signals is shielded from interference.

A covering layer 14 made from molding resin material gives the semiconductor structure the shape of a rectangular block.

The hardness of the covering layer 14 is softer because the processes after forming the covering layer 14 are not high temperature. The stiffness of the structure under high temperature conditions is provided by protecting layer 12, which prevents the active region 11 from heat damage.

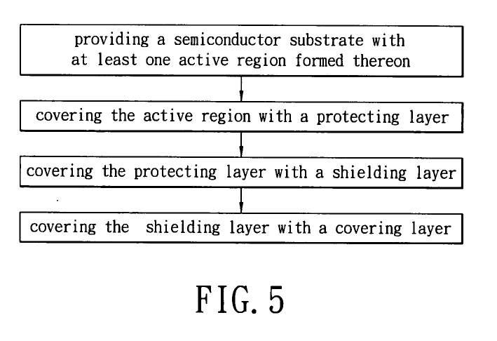

Please refer to FIG. 5, which shows a method for manufacturing the shielding structure. Step 1 is to provide a semiconductor substrate 1 and at least one active region 11 formed thereon. Step 2 is to provide a protecting layer 12 disposed on the active region 11 by semiconductor-manufacturing processes. Step 3 is to provide a shielding layer 13 disposed on the protecting layer 12 by a semiconductor-manufacturing process. Step 4 is to provide a covering layer 14 disposed on shielding layer 13 by a molding procedure.

In step 1 a gallium arsenide (GaAs) substrate is used but use of other materials is possible. In step 2 the protecting layer 12 is disposed on the active region 11 and the shape of the protecting layer 12 matches that of the active region 11. The two protecting layers 12 and 12′ respectively cover two active regions 11 and one active region 11′. In step 3, the shielding layer 13 is a metal layer applied by a metal sputtering process common in the manufacture of semiconductors. The shielding layer 13 is formed by common semiconductor-manufacturing processes so as to reduce manufacturing time and costs. The shape of shielding layer 13 is matching the shape of protecting layer 12 and the shielding effect of the shielding layer 13 is further improved because the defect of the shielding layer 13 is less than the prior metal casing. The thickness of shielding layer 13 is controlled by means of the semiconductor-manufacturing process which allows a high precision of the layer thickness.

In step 4, the covering layer 14 is disposed on shielding layer 13 by a molding process.

The protecting layer 12 formed in step 2 is manufactured by semiconductor-manufacturing processes but is not restricted to tetraethoxysilane (TEOS) material or a silicon nitride material. The protecting layer 12 is harder than the covering layer 14 and has better heat resisting properties. The protecting layer 12 does not soften under high temperature so that the protecting layer 12 protects the active region 11 from heat damage.

Accordingly, the present invention is provided for an efficient and low-interference shielding structure with automatic-controlled procedures.

In summary, the present invention achieves the following advantages:

1. The protecting layer 12 is made by semiconductor-manufacturing processes and has better stiffness, hardness and heat resisting properties so that the semiconductor substrate 1 is protected by protecting layer 12 from deformation through high temperature.

2. The shielding layer 13 prevents interference of radiation emitted by the semiconductor with other devices.

In other words, the present invention provides a shielding structure with an additional heat resistance effect.

Although the present invention has been described with reference to the foregoing preferred embodiment, it will be understood that the invention is not limited to the details thereof. Various equivalent variations and modifications may occur to those skilled in the art in view of the teachings of the present invention. Thus, all such variations and equivalent modifications are embraced within the scope of the invention as defined in the appended claims.

What is claimed is:

1. A shielding structure for semiconductors comprising:
a semiconductor substrate;
at least one active region on one side of the semiconductor substrate;
a protecting layer disposed on the active region by semiconductor-manufacturing processes;
a shielding layer disposed on the protecting layer by semiconductor-manufacturing processes; and a covering layer disposed on the shielding layer;
wherein the protecting layer is harder than the shielding layer.

2. The shielding structure according to claim 1, wherein the protecting layer is made of tetraethoxysilane (TEOS).

3. The shielding structure according to claim 1, wherein the protecting layer is made from a silicon nitride material.

4. The shielding structure according to claim 1, wherein the shielding layer is a metal layer.

5. The shielding structure according to claim 4, wherein the metal layer is made by the semiconductor processes and the metal layer has a predetermined thickness.

6. The shielding structure according to claim 1, wherein the covering layer is made from a molding resin material.

7. A manufacturing method for manufacturing the shielding structure according to claim 1, comprising:
(a) providing a semiconductor substrate and at least one active region formed thereon;
(b) providing a protecting layer disposed on the active region by semiconductor-manufacturing processes;
(c) providing a shielding layer disposed on the protecting layer by semiconductor-manufacturing processes; and
(d) providing a covering layer disposed on the shielding layer.

8. The manufacturing method according to claim 7, wherein in step (c) the shielding layer is a metal layer.

9. The manufacturing method according to claim 8, wherein the semiconductor-manufacturing processes includes a sputtering process.

10. The manufacturing method according to claim 7, wherein in step (d) the covering layer is made from a resin material by a molding process.

11. The manufacturing method according to claim 7, wherein in step (b) the protecting layer is made from tetraethoxysilane (TEOS).

12. The manufacturing method according to claim 7, wherein in step (b) the protecting layer is made from a silicon nitride material.

13. The manufacturing method according to claim 7, wherein the protecting layer is harder than the shielding layer
